(19) United States
(12) Patent Application Publication
(10) Pub. No.: US 2024/0036484 A1
(43) Pub. Date: Feb. 1, 2024

(54) METHOD OF METROLOGY AND ASSOCIATED APPARATUSES

(71) Applicant: ASML Netherlands B.V., Veldhoven (NL)

(72) Inventors: Timothy Dugan DAVIS, Portland, OR (US); Simon Gijsbert Josephus MATHIJSSEN, Rosmalen (NL); Kaustuve BHATTACHARYYA, Veldhoven (NL); Sebastianus Adrianus GOORDEN, Eindhoven (NL); Armand Eugene Albert KOOLEN, Nuth (NL); Sera JEON, Seoul (KR); Shuo-Chun LIN, Hsinchu City (TW)

(73) Assignee: ASML Netherlands B.V., Veldhoven (NL)

(21) Appl. No.: 18/265,606

(22) PCT Filed: Dec. 2, 2021
(86) PCT No.: PCT/EP2021/083968

§ 371 Date: Jun. 6, 2023

Related U.S. Application Data
(60) Provisional application No. 63/122,641, filed on Dec. 8, 2020.

(51) Int. Cl. G03F 9/00; G03F 7/00

(52) U.S. Cl. CPC G03F 9/7019; G03F 9/7092; G03F 7/70633; G03F 7/70641

(57) ABSTRACT

Disclosed is a method of metrology. The method comprises measuring at least one surrounding observable parameter relating to a surrounding signal contribution to a metrology signal which comprises a contribution to said metrology signal which is not attributable to at least one target being measured and determining a correction from said surrounding signal observable parameter. The correction is used to correct first measurement data relating to measurement of one or more targets using measurement radiation forming a measurement spot on one or more of said one or more targets which is larger than one of said targets.

### CROSS-REFERENCE TO RELATED APPLICATIONS

This application claims priority of U.S. application 63/122,641 which was filed on Dec. 8, 2020 and which is incorporated herein in its entirety by reference.

### FIELD OF THE INVENTION

The present invention relates to a metrology apparatus and methods usable, for example, to perform metrology in the manufacture of devices by lithographic techniques.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In lithographic processes, it is desirable frequently to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field. These devices direct a beam of radiation onto a target and measure one or more properties of the scattered radiation—e.g., intensity at a single angle of reflection as a function of wavelength; intensity at one or more wavelengths as a function of reflected angle; or polarization as a function of reflected angle—to obtain a diffraction “spectrum” from which a property of interest of the target can be determined.

Examples of known scatterometers include angle-resolved scatterometers of the type described in US2006033921A1 and US2010201963A1. The targets used by such scatterometers are relatively large, e.g., 40 μm by 40 μm; the target and the measurement beam generates a spot that is smaller than the grating (i.e., the target is underfilled). Examples of dark field imaging metrology can be found in international patent applications US20100328655A1 and US2011069292A1 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot (i.e., the target is overfilled) and may be surrounded by product structures on a wafer. Multiple gratings can be measured in one image, using a composite grating target. The contents of all these applications are also incorporated herein by reference.

A consequence of overfilled metrology techniques is that other structures may be captured within the measurement spot leading to crosstalk (contributions from neighboring structures in the measurement signal). This consequence is equally applicable to overfilled overlay/focus metrology and overfilled alignment.

As such, it would be desirable to improve the accuracy of metrology on overfilled targets.

### SUMMARY OF THE INVENTION

The invention in a first aspect provides a method of metrology comprising: measuring at least one surrounding observable parameter relating to a surrounding signal contribution to a metrology signal which comprises a contribution to said metrology signal which is not attributable to at least one target being measured; determining a correction from said surrounding signal observable parameter; obtaining first measurement data relating to measurement of one or more targets using measurement radiation forming a measurement spot on one or more of said one or more targets which is larger than one of said targets; and applying said correction to the first measurement data.

The invention in a second aspect provides a metrology apparatus, comprising: a support for said substrate having at least one of said targets and said product structure thereon; an optical system for measuring each target; a processor; and a computer program carrier comprising a computer program operable such that the processor can control the metrology apparatus to perform the method of the first aspect.

The invention yet further provides a computer program product comprising machine-readable instructions for causing a processor to perform the method of the first aspect, and associated metrology apparatus, lithographic system and method of manufacturing devices.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus;

FIG. 2 depicts a lithographic cell or cluster in which an inspection apparatus according to the present invention may be used;

FIGS. 3(a)-3(b) illustrate schematically an inspection apparatus adapted to perform angle-resolved scatterometry and dark-field imaging inspection methods;

FIG. 4 is a schematic illustration of an alignment sensor adaptable according to an embodiment of the invention;

FIG. 5 is a schematic illustration of an alternative metrology device adaptable according to an embodiment of the invention;

FIGS. 6(a)-6(c) comprise 6(a) a pupil image of input radiation 6(b) pupil image of off-axis illumination beams illustrating an operational principle of the metrology device of FIG. 5; and 6(c) pupil image of off-axis illumination beams illustrating another operational principle of the metrology device of FIG. 5;

FIG. 7 schematically illustrates an overfilled measurement which is affected by surrounding structure performed on a metrology target; and

FIG. 8 schematically illustrates measurement of a non-visible target structure, where the non-visible target structure and methods based on metrology of said non-visible target structure are according to embodiments of the invention.

### DETAILED DESCRIPTION OF EXEMPLARY EMBODIMENTS

Before describing embodiments of the invention in detail, it is instructive to present an example environment in which embodiments of the present invention may be implemented.

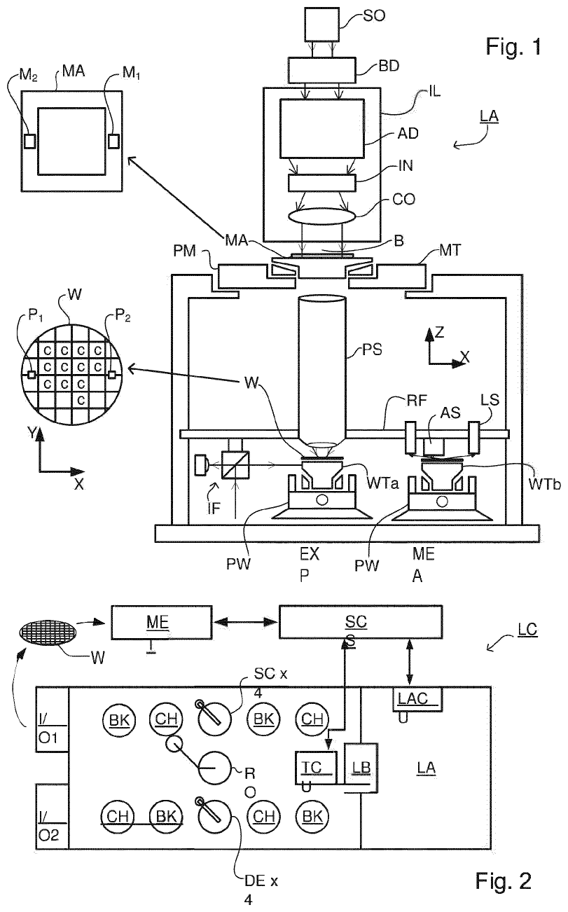

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support holds the patterning device in a manner that depends on the orientation of the patterning device, the design of the lithographic apparatus, and other conditions, such as for example whether or not the patterning device is held in a vacuum environment. The patterning device support can take many forms; the patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., reticle/mask) MA with respect to the path of the radiation beam B, e.g., after mechanical retrieval from a mask library, or during a scan.

Patterning device (e.g., reticle/mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment mark may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates, especially if the inspection can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates but may still provide useful information.

One example of a metrology apparatus suitable for metrology in a lithographic monitoring context is a scatterometer. Scatterometers may comprise dark-field scatterometers (where the zeroth order is blocked before the detector such that only diffracted higher orders are captured) and bright-field scatterometers which also capture the zeroth order. Some scatterometers are capable of both bright-field and dark-field metrology. A known type of dark-field scatterometry technique compares the intensity of each of a pair of complementary higher diffraction orders (e.g., compares the respective intensities of the +1 and −1 orders) to determine asymmetry in the measured target (the magnitude of the intensity difference scales with the asymmetry. The target asymmetry can in turn be used to determine various parameters of interest such as overlay or the focus setting when the target was formed.

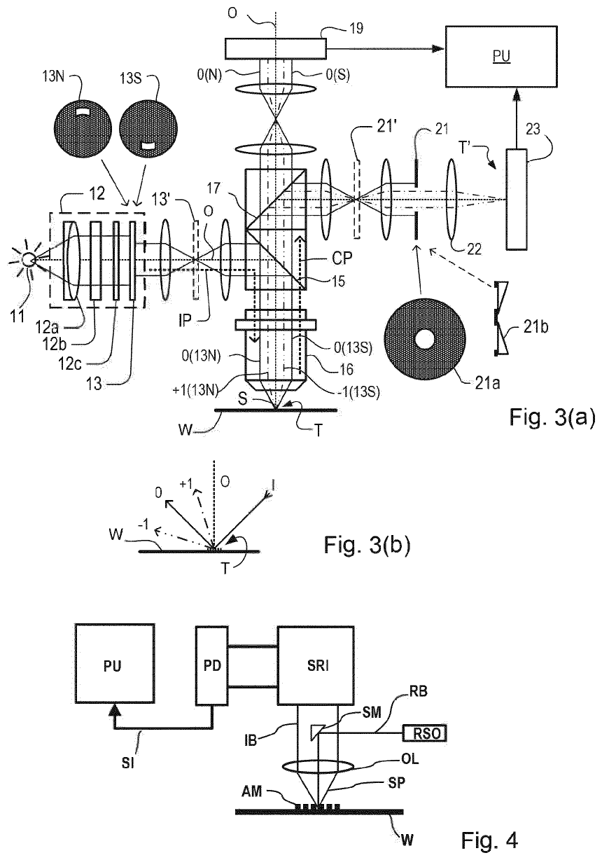

A metrology apparatus suitable for use in embodiments of the invention is shown in FIG. 3(a). Note that this is only one example of a suitable metrology apparatus. An alternative suitable metrology apparatus may use EUV radiation such as, for example, that disclosed in WO2017/186483A1. A target structure T and diffracted rays of measurement radiation used to illuminate the target structure are illustrated in more detail in FIG. 3(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 3(b), target structure T is placed with substrate W normal to the optical axis O of objective lens 16. The substrate W may be supported by a support (not shown). A ray of measurement radiation I impinging on target structure T from an angle off the axis O gives rise to a zeroth order ray (solid line 0) and two first order rays (dot-chain line +1 and double dot-chain line −1), hereafter referred to as a pair of complementary diffraction orders. It should be noted that the pair of complementary diffraction orders may be any higher order pair; e.g., the +2, −2 pair etc. and is not limited to the first order complementary pair. It should be remembered that with an overfilled small target structure, these rays are just one of many parallel rays covering the area of the substrate including metrology target structure T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the target structures and the illumination angles can be designed or adjusted so that the first order rays entering the objective lens are closely aligned with the central optical axis. The rays illustrated in FIGS. 3(a) and 3(b) are shown somewhat off axis, purely to enable them to be more easily distinguished in the diagram.

At least the 0 and +1 orders diffracted by the target structure T on substrate W are collected by objective lens 16 and directed back through beam splitter 15. Returning to FIG. 3(a), both the first and second illumination modes are illustrated, by designating diametrically opposite apertures labeled as north (N) and south (S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image or angle resolved image) of the target structure on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes, which include, for example reconstruction or metrology based on asymmetry in the pupil plane image.

In the second measurement branch, optical system 20, 22 forms an image of the target structure T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

Another type of metrology apparatus is an alignment sensor. A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

A mark or alignment mark (which is more generally a type of target), may comprise a series of bars formed on or in a layer provided on the substrate or formed (directly) in the substrate. The bars may be regularly spaced and act as grating lines so that the mark can be regarded as a diffraction grating with a well-known spatial period (pitch). Depending on the orientation of these grating lines, a mark may be designed to allow measurement of a position along the X axis, or along the Y axis (which is oriented substantially perpendicular to the X axis). A mark comprising bars that are arranged at +45 degrees and/or −45 degrees with respect to both the X- and Y-axes allows for a combined X- and Y-measurement using techniques as described in US2009/195768A, which is incorporated by reference.

The alignment sensor scans each mark optically with a spot of radiation to obtain a periodically varying signal, such as a sine wave. The phase of this signal is analyzed, to determine the position of the mark and, hence, of the substrate relative to the alignment sensor, which, in turn, is fixated relative to a reference frame of a lithographic apparatus. So-called coarse and fine marks may be provided, related to different (coarse and fine) mark dimensions, so that the alignment sensor can distinguish between different cycles of the periodic signal, as well as the exact position (phase) within a cycle. Marks of different pitches may also be used for this purpose.

Measuring the position of the marks may also provide information on a deformation of the substrate on which the marks are provided, for example in the form of a wafer grid. Deformation of the substrate may occur by, for example, electrostatic clamping of the substrate to the substrate table and/or heating of the substrate when the substrate is exposed to radiation.

FIG. 4 is a schematic block diagram of an embodiment of a known alignment sensor AS. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the mark AM is collimated (in this example via the objective lens OL) into an information-carrying beam IB. The term “diffracted” is intended to include zero-order diffraction from the mark (which may be referred to as reflection). A self-referencing interferometer SRI, e.g. of the type disclosed in U.S. Pat. No. 6,961,116 mentioned above, interferes the beam IB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

Intensity signals SI are supplied to a processing unit PU. By a combination of optical processing in the block SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels are repeated at different wavelengths for increased accuracy and/or for robust detection of the mark irrespective of the materials from which the mark is made, and materials on and/or below which the mark is provided. Improvements in performing and processing such multiple wavelength measurements are disclosed below.

Another specific type of metrology sensor, which has both alignment and product/process monitoring metrology applications, has recently been recently described in European applications EP18195488.4 and EP19150245.9, which are incorporated herein by reference. This describes a metrology device with optimized coherence. More specifically, the metrology device is configured to produce a plurality of spatially incoherent beams of measurement illumination, each of said beams (or both beams of measurement pairs of said beams, each measurement pair corresponding to a measurement direction) having corresponding regions within their cross-section for which the phase relationship between the beams at these regions is known; i.e., there is mutual spatial coherence for the corresponding regions.

Such a metrology device is able to measure small pitch targets with acceptable (minimal) interference artifacts (speckle) and will also be operable in a dark-field mode. Such a metrology device may be used as a position or alignment sensor for measuring substrate position (e.g., measuring the position of a periodic structure or alignment mark with respect to a fixed reference position). However, the metrology device is also usable for measurement of overlay (e.g., measurement of relative position of periodic structures in different layers, or even the same layer in the case of stitching marks). The metrology device is also able to measure asymmetry in periodic structures, and therefore could be used to measure any parameter which is based on a target asymmetry measurement (e.g., overlay using diffraction based overlay (DBO) techniques or focus using diffraction based focus (DBF) techniques).

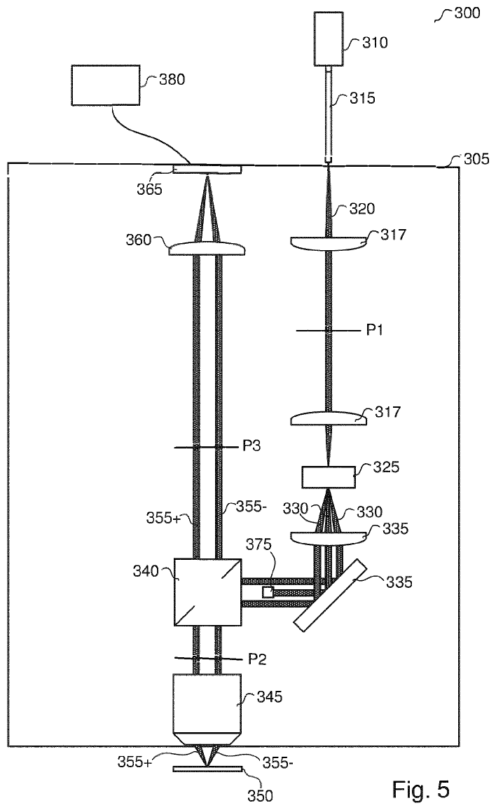

FIG. 5 shows a possible implementation of such a metrology device. The metrology device essentially operates as a standard microscope with a novel illumination mode. The metrology device 300 comprises an optical module 305 comprising the main components of the device. An illumination source 310 (which may be located outside the module 305 and optically coupled thereto by a multimode fiber 315) provides a spatially incoherent radiation beam 320 to the optical module 305. Optical components 317 deliver the spatially incoherent radiation beam 320 to a coherent off-axis illumination generator 325. This component is of particular importance to the concepts herein and will be described in greater detail. The coherent off-axis illumination generator 325 generates a plurality (e.g., four) off-axis beams 330 from the spatially incoherent radiation beam 320. The characteristics of these off-axis beams 330 will be described in detail further below. The zeroth order of the illumination generator may be blocked by an illumination zero order block element 375. This zeroth order will only be present for some of the coherent off-axis illumination generator examples described in this document (e.g., phase grating based illumination generators), and therefore may be omitted when such zeroth order illumination is not generated. The off-axis beams 330 are delivered (via optical components 335 and) a spot mirror 340 to an (e.g., high NA) objective lens 345. The objective lens focusses the off-axis beams 330 onto a sample (e.g., periodic structure/alignment mark) located on a substrate 350, where they scatter and diffract. The scattered higher diffraction orders 355+, 355− (e.g., +1 and −1 orders respectively), propagate back via the spot mirror 340, and are focused by optical component 360 onto a sensor or camera 365 where they interfere to form an interference pattern. A processor 380 running suitable software can then process the image(s) of the interference pattern captured by camera 365.

The zeroth order diffracted (specularly reflected) radiation is blocked at a suitable location in the detection branch; e.g., by the spot mirror 340 and/or a separate detection zero-order block element. It should be noted that there is a zeroth order reflection for each of the off-axis illumination beams, i.e. in the current embodiment there are four of these zeroth order reflections in total. An example aperture profile suitable for blocking the four zeroth order reflections is shown in FIGS. 4(b) and (c), labelled 422. As such, the metrology device operated as a “dark field” metrology device.

A main concept of the proposed metrology device is to induce spatial coherence in the measurement illumination only where required. More specifically, spatial coherence is induced between corresponding sets of pupil points in each of the off-axis beams 330. More specifically, a set of pupil points comprises a corresponding single pupil point in each of the off-axis beams, the set of pupil points being mutually spatially coherent, but where each pupil point is incoherent with respect to all other pupil points in the same beam. By optimizing the coherence of the measurement illumination in this manner, it becomes feasible to perform dark-field off-axis illumination on small pitch targets, but with minimal speckle artifacts as each off-axis beam 330 is spatially incoherent.

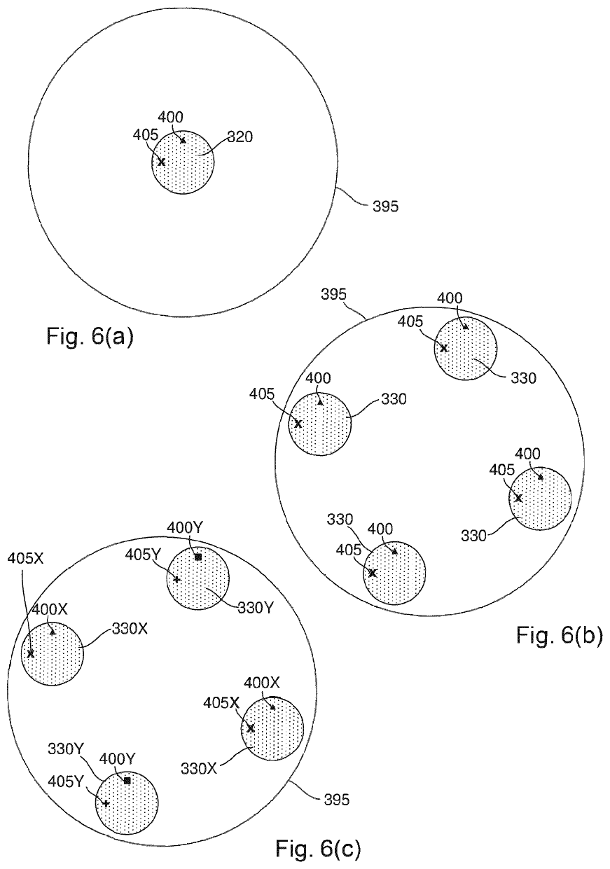

FIG. 6 shows three pupil images to illustrate the concept. FIG. 6(a) shows a first pupil image which relates to pupil plane P1 in FIG. 5, and FIGS. 6(b) and 6(c) each show a second pupil image which relates to pupil plane P2 in FIG. 5. FIG. 6(a) shows (in cross-section) the spatially incoherent radiation beam 320, and FIGS. 6(b) and 6(c) show (in cross-section) the off-axis beams 330 generated by coherent off-axis illumination generator 325 in two different embodiments. In each case, the extent of the outer circle 395 corresponds to the maximum detection NA of the microscope objective; this may be, purely by way of an example 0.95 NA.

The triangles 400 in each of the pupils indicate a set of pupil points that are spatially coherent with respect to each other. Similarly, the crosses 405 indicate another set of pupil points which are spatially coherent with respect to each other. The triangles are spatially incoherent with respect to crosses and all other pupil points corresponding to beam propagation. The general principle (in the example shown in FIG. 6(b)) is that each set of pupil points which are mutually spatially coherent (each coherent set of points) have identical spacings within the illumination pupil P2 as all other coherent sets of points. As such, in this embodiment, each coherent sets of points is a translation within the pupil of all other coherent sets of points.

In FIG. 6(b), the spacing between each pupil point of the first coherent set of points represented by triangles 400 must be equal to the spacing between each pupil point of the coherent set of points represented by crosses 405. ‘Spacing’ in this context is directional, i.e., the set of crosses (second set of points) is not allowed to be rotated with respect to the set of triangles (first set of points). As such, each of the off-axis beams 330 comprises by itself incoherent radiation; however the off-axis beams 330 together comprise identical beams having corresponding sets of points within their cross-section that have a known phase relationship (spatial coherence). It should be noted that it is not necessary for the points of each set of points to be equally spaced (e.g., the spacing between the four triangles 405 in this example is not required to be equal). As such, the off-axis beams 330 do not have to be arranged symmetrically within the pupil.

FIG. 6(c) shows that this basic concept can be extended to providing for a mutual spatial coherence between only the beams corresponding to a single measurement direction where beams 330X correspond to a first direction (X-direction) and beams 330Y correspond to a second direction (Y-direction). In this example, the squares and plus signs each indicate a set of pupil points which correspond to, but are not necessarily spatially coherent with, the sets of pupil points represented by the triangles and crosses. However, the crosses are mutually spatially coherent, as are the plus signs, and the crosses are a geometric translation in the pupil of the plus signs. As such, in FIG. 6(c), the off-axis beams are only pair-wise coherent.

In this embodiment, the off-axis beams are considered separately by direction, e.g., X direction 330X and Y direction 330Y. The pair of beams 330X which generate the captured X direction diffraction orders need only be coherent with one another (such that pair of points 400X are mutually coherent, as are pair of points 405X). Similarly the pair of beams 330Y which generate the captured Y direction diffraction orders need only be coherent with one another (such that pair of points 400Y are mutually coherent, as are pair of points 405Y). However, there does not need to be coherence between the pairs of points 400X and 400Y, nor between the pairs of points 405X and 405Y. As such there are pairs of coherent points comprised in the pairs of off-axis beams corresponding to each considered measurement direction. As before, for each pair of beams corresponding to a measurement direction, each pair of coherent points is a geometric translation within the pupil of all the other coherent pairs of points.

Overfilled metrology techniques, where the metrology target is overfilled (i.e., target is smaller than the measurement spot), enables metrology targets to be smaller, thereby saving space, enabling more metrology targets to be accommodated and/or enabling the metrology targets to be located within product areas or other strategic locations.

Current diffraction based measurements on overfilled targets, including both post-exposure measurements (e.g., overlay or focus measurements) or pre-exposure measurements (e.g., alignment), are susceptible to crosstalk from numerous contributors. These contributors comprise, for example, residual sensor or camera ghosts or artifacts, and information from neighboring features (e.g., product structure, dummy structure and/or other metrology targets). This crosstalk contributes to the measurement signal leading to an error (i.e., the crosstalk contribution is not related to a parameter of interest).

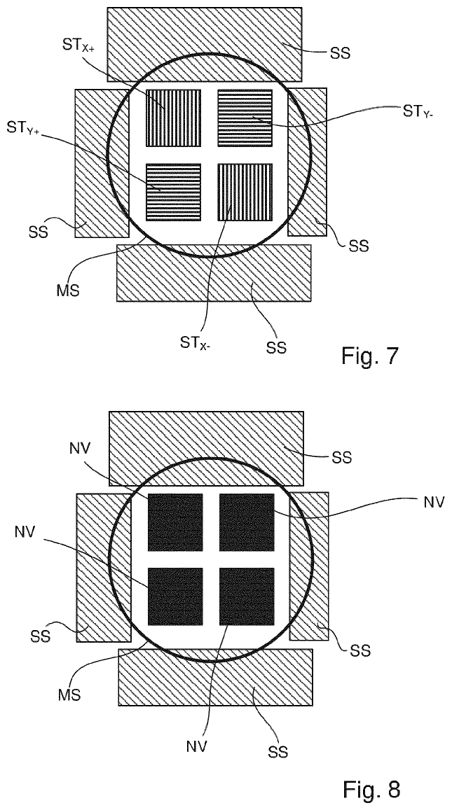

FIG. 7 illustrates a specific example illustrating the crosstalk issue in relation to a measurement of a metrology target (e.g., an overlay target) comprising two X direction sub targets ST_{X+}, ST_{X-} and two Y direction sub targets ST_{Y+}, ST_{Y-}. A measurement of such a target may be performed using a measurement spot MS sufficiently large to measure all four sub targets simultaneously. However, the measurement signal relating to targets of one direction (e.g., the measurement of the two X direction sub targets ST_{X+}, ST_{X-}), may be affected by (e.g., comprise a contribution attributable to) radiation scattered from surrounding structures SS. Surrounding structures SS in this context may comprise background dummy patterns and/or neighboring product structure during a measurement of a target. Surrounding structures SS in this context may also include neighboring metrology features, such as other overlay pads/sub-targets or alignment marks (e.g., two Y direction sub targets ST_{Y+}, ST_{Y} when the X direction targets are being considered). This crosstalk can be a problem for both pre-exposure metrology (alignment) and post-exposure metrology (e.g., overlay, focus etc.).

Most present correction strategies assume the absence of dummy/target structures. However, there may actually be an intensity landscape around a metrology target, which creates (in an overfilled measurement) an asymmetry contribution at the detector/camera.

In an alignment context, the effects of surrounding structures are considered to be one of the biggest issues for performing wafer alignment on smaller alignment targets (or alignment marks), e.g., such as 10 μm×10 μm marks (or, more generally, marks/targets smaller than 40 μm, 30 μm, 20 μm or 15 μm in one or both directions of the substrate plane). For example, some of the radiation that comes from a surrounding structure on the wafer scatters from edges (e.g., of the pupil stop in the metrology tool), or high-frequency imperfections (e.g. scratch-dig) in the optics. This radiation ends up in the region-of-interest and leads to an error in the alignment signal. Also, surrounding structures impact process effects (e.g. asymmetry and/or layer thickness) of the mark, for example due to polishing steps, which can also lead to errors in the alignment signal. Both of these effects are expected to have an absolute alignment accuracy impact as well as a wafer-to-wafer varying accuracy impact.

It is proposed herein to quantify and correct for the crosstalk by calibrating and removing its contribution to the metrology signal. Such a correction may be based on a determination of a surrounding signal contribution to a measurement, where the surrounding signal contribution may describe any metrology signal contributor resultant from anything outside of the target of interest; e.g., which may propagate spurious radiation back into the metrology sensor which should be measuring only metrology signal from the target. In this context, the metrology signal may comprise the radiation which is scattered from the actual target or sub-target thereof (and/or a region of interest within the target).

A first embodiment comprises calibrating the quantity of radiation from surrounding structure which bleeds into and therefore contributes to the actual metrology signal. Following the calibration of this stray radiation from neighboring features, a mathematical correction can be determined and applied to the measurement signal, which corrects for this unwanted contribution. The calibration may be performed via physical measurements (calibration measurements) using a metrology tool, which may comprise offline measurements (e.g., not during a production phase). In one example a calibration may be performed based on calibration measurements on a special “non-visible target” which is designed to be invisible to the metrology sensor. The non-visible target and associated calibration is described below.

In another embodiment, such a calibration may comprise, for example, measuring swing curves respectively for the target and for the surrounding structure, and then comparing the swing curves. A swing curve may describe a variation of a measurement parameter value (e.g., any observable parameter such as intensity, intensity imbalance, phase, stack sensitivity or any other related parameter) with an illumination condition used to obtain the measurement parameter values. The comparison may use statistical methods (e.g., a component analysis such as principal component analysis, independent component analysis and/or singular value decomposition etc.).

In an embodiment, such a method may comprise comparing the swing curve (e.g. asymmetry as a function of wavelength) of the target and the swing curve of the surrounding structure. When the wavelength dependence of the target and the surrounding structure are significantly different (e.g., due to different structures), they can be disentangled using known statistical techniques (PCA, ICA etc.) to obtain respective fingerprints. Based on these statistical techniques, the effect of the surrounding structure may be removed by removing a fingerprint relating to the surrounding structure.

The calibration measurements may comprise target measurement data comprising target observable parameter values relating to respective regions of interest (ROIs) of a target measurement (e.g., one or more first ROIs relating to the target and surrounding observable parameter data from one or more second ROIs relating to the surrounding (which may include a neighboring target or sub-target)). Alternatively, the measurements may be performed separately on target and surrounding. Also, the observable parameter on the surrounding structure could be measured with a separate tool than that used to measure the target.

By way of a specific example, the correction may be determined for correction of a measurement on a typical compound target which comprises one or more respective sub-targets or pads for each of the X and Y directions (e.g., the two directions of the substrate plane). Contributions from the target for the other direction may impact the measurement signal from the sub-target being measured. For example, a signal from an X-target sub-pad may be obtained, e.g., to determine a parameter such as overlay in the X direction, which may comprise a signal contribution from the Y sub-target. The comparison of the swing curves may comprise a comparison of a first swing curve from the X target and a second swing curve from the Y target, to determine the contribution from the Y target in the X target signal.

It may be noted that a surrounding signal contribution may also be resultant from an asymmetric sensor, at least in part, and at least some of the methods disclosed herein can also correct for such asymmetric sensor contributions. Where such a method is based on a calibration, it will therefore be tool dependent.

In an embodiment, the proposed method may comprise the following two steps:
1. Measure any suitable surrounding observable parameter on the surrounding structure (e.g., visible on the camera due to overfill of the mark); and
2. Correct first measurement data based on the observable parameter. For example, a correction for a measurement may comprise the product of the observable parameter and one or more constants or coefficients (or more generally the corrected measurement may be a function of the observable parameter). Such a function may, for example, translate the observable parameter into a correction which compensates for the surrounding signal contribution. Such a method may comprise determining a correction relationship (e.g., function or coefficient), e.g., in a calibration phase or otherwise. In an alignment context, by way of specific example, an aligned position APD_{corrected} may be calculated as APD_{corrected}=APD_{measured}+constant*observable parameter.

Such an approach is similar to optimal color (and/or intensity) weighting (OCW) approaches such as described in US publication US2019/0094721 A1 (which is incorporated herein by reference). A main difference is that the observable parameter is not an aligned position at a different color or an intensity imbalance (i.e., relating to the target itself), but something measured on a surrounding structure.

The observable measured on the surrounding structure could be a measure of or related to one or more of, for example:
Signal strength or (e.g., average) intensity over one or more regions of interest (ROI) on the camera/detector corresponding to the surrounding structure;
Amplitude of an interference pattern (e.g., this is the quantity determined by the a fitting algorithm in the optimized coherence metrology tool such as illustrated in FIG. 5) e.g., within one or more regions of interest (ROI) on the camera/detector corresponding to the surrounding structure;
Aligned position (standard quantity determined by aforementioned fitting algorithm, i.e., essentially the phase difference between +1st and −1st (and/or higher) orders. This may be directly measured by the fringe position in one or more regions of interest (ROI) on the camera/detector corresponding to the surrounding structure);
Asymmetry (measuring the asymmetry of surrounding structure may be of particular interest when any asymmetry of surrounding structure and grating asymmetry of the mark/target are correlated). Asymmetry is a standard quantity for dark field metrology devices such as illustrated in FIG. 4; and can also be measured by a metrology device such as illustrated in FIG. 5 which comprise a detection branch that detect intensity imbalance in parallel to the standard interference pattern);
Intensity imbalance;
Fringe visibility (a more asymmetric surrounding structure grating will have a reduced fringe visibility);
A difference between aligned positions (or more generally measurement values) for different colors (if alignment measurements at multiple colors are available, grating asymmetry can be deduced. This can also replace intensity imbalance in case no intensity imbalance measurement is available).

In such an embodiment, an important consideration relates to how the constant(s) in the correction is/are determined. An alignment embodiment may comprise, for example, performing wafer alignment without the correction, exposing the wafers and measuring overlay on the exposed wafers in a calibration phase. From the overlay measurements it is possible to optimize the constant(s) (and/or which observable parameter should be used) such that a correction (e.g., corresponding function or coefficient/constant) can be determined which would have improved overlay performance (i.e., minimizes overlay error), had it been applied during wafer alignment (i.e., to the alignment data obtained in the first step). Such a method is similar to that used to determine weights in present OCW methods.

Another embodiment may comprise using a shadow mode during a wafer manufacturing process, which continuously monitors whether updating the correction constant and/or observable parameter would improve the overlay (assuming a feedback signal such as overlay is available) or any other performance parameter indicative of quality of the lithographic process. Such an approach may also be possible without a feedback signal, if the relation between the observable at the surrounding structure and the required (e.g., alignment position) correction is understood/known/modeled. This may be based on e.g., a completely accurate sensor (and stack) model; however this is difficult to achieve. One way to mitigate may be to e.g., measure how much light scatters from the surrounding structure onto the target/mark (region-of-interest) and simulate/model the impact of this on the aligned position or other parameter of interest.

In many of the described embodiments, a plurality of different observable parameters (and corresponding correction constants) may be used at the same time. This may, for example, be necessary and/or give improved performance if several independent process variations occur in the surrounding structure which require correction (since the number of measurements/observables needs to be at least equal to the number of variables to be corrected).

The method described here could provide a measurement correction (e.g., an aligned position correction) per location within a target/mark. Such an embodiment may impose a weighting on the correction coefficient as function of position with respect to the surrounding structure, e.g., a smaller correction coefficient may be imposed further away from the surrounding structure). This may be particularly beneficial when using an optimized coherence tool, as such illustrated in FIG. 5, or any other metrology tool which can obtain a measurement value as a function of target/mark position (e.g., measure local APD or aligned position per location within the mark), thereby enabling correction for e.g., local mark deformations.

The methods described above may be combined with OC(I)W (optimal color and intensity weighting).

While the methods described above in the context of alignment, are described in relation to measurement using an image based tool (e.g., the optimized coherence image based tool of FIG. 5), the methods are also applicable to a more conventional (e.g., SRI based) alignment sensor such as depicted in FIG. 4 for measurement on small marks. Such a method may be based on an assuming that it is not possible to perfectly underfill small marks. Alternatively or in addition, it is possible to purposely use a longer scan length over the mark such that the surrounding structure is captured in the measurement (e.g., because it has useful information).

While the above description describes applying a linear correction model, a higher-order correction model may also be used. The correction model could also be a machine learned model such as a neural network (and therefore suitably trained).

A second method utilizes a special target, referred to herein as a non-visible target as it provides no signal to the metrology tool (it cannot be seen by the metrology tool). Such a target may be used to directly measure the surrounding signal contribution, rather than infer this surrounding signal contribution from another observable parameter. For example, a non-visible target may be located in the vicinity of a metrology target (e.g., inside of an area in which a parameter of interest is being measured). Any region of interest on the camera image corresponding to the actual non-visible target should comprise no signal (e.g., no intensity), and therefore any signal detected in the region can be assumed to be the surrounding signal contribution. In an embodiment, this directly measured surrounding signal contribution from a measurement of the non-visible target can simply be subtracted from the metrology signal from the metrology target. This also directly corrects for residual calibration errors.

The non-visible target may, for example, comprise a grating having a period which does not generate propagating diffraction orders that can be captured by the metrology tool. Only a zeroth order will be generated or at least propagate as far as any collection optics. Radiation from this target is therefore not absorbed, but is reflected into the zeroth order of the illumination tool, where it is blocked (e.g., when using a tool in a dark-field mode; the metrology tools of FIGS. 3 and 5 for example are operable in dark field mode). Any “higher” diffraction orders are evanescent, hence they will nor propagate to the collection optics/detector and not be “seen” by the metrology tool. In this way, the dummy targets are not visible. The non-visible target may alternatively comprise a reflective area or anything else which is invisible to the metrology target (e.g., only scatters/reflects propagating radiation in the zeroth order).

FIG. 8 illustrates a non-visible target in the context of the (e.g., overlay) metrology of FIG. 7. Such a non-visible target comprises one or more non-visible regions NV having the properties described above. Any signal detected in regions corresponding to the non-visible regions NV when such a target is measured is attributable to the surrounding structure SS (and possibly any sensor asymmetry). As such, this signal can be subtracted from target measurements.

The non-visible target may comprise a form (e.g., outline/shape) similar to or the same as to its corresponding metrology target (e.g., the metrology target for which corrections are to be determined). In this way, the configuration of the surrounding structure with respect to the target can be best represented.

While the non-visible target can be measured during production as described to directly measure the surrounding signal contribution for a target measurement, it is not always desirable to measure such a target in this way (e.g., there will be a throughput penalty associated with the additional measurements of the non-visible target). Therefore another embodiment comprises only measuring the non-visible target in a calibration to determine a correction coefficient or function, and applying (e.g., during a manufacturing process) the correction coefficient or function to measurements of surrounding structure (e.g., measurements of an observable parameter). Such measurements of surrounding structure can be determined from the same image as that of the target; i.e., thereby incurring no throughput penalty. Of course, the surrounding structure may optionally be measured separately.

By determining a function which connects the background asymmetry as measured to the asymmetry (or intensity/phase) of the non-visible target, there is no need to measure the non-visible target after calibration. The function can be determined once (e.g., per stack/illumination condition) in a single calibration using the non-visible target. Subsequently, only the surrounding structure needs measuring and the measured values converted using the determined relationship so as to determine the intensity and/or phase contribution in the actual target measurement which is due to the parasitic leakage from the surrounding structure. This contribution can then be subtracted from the measured intensity and/or phase to obtain the correct value (i.e., without the surrounding signal contribution/parasitic leakage term). Such a method is able to accommodate differences in the stack (e.g., different backgrounds on the wafer) between the calibration site and the measurement site.

The calibration may comprise measuring the non-visible target and determining the surrounding signal contribution (e.g., once) for each nominal stack, and for each recipe setting that will be used. In each case, corresponding measurements of one or more observable parameters of the surrounding structure are made (e.g., from the same images or otherwise). A relationship between the surrounding signal contribution and one or more observable parameters can then be determined (e.g., per nominal stack/measurement recipe combination). By way of a simple example, if the intensity in an ROI corresponding to a surrounding location is 20 times that of the intensity in an ROI corresponding to the non-visible target, the determined function may simply be a coefficient/scaling factor of 0.05. As before, more complex or higher order functions/models may be determined. Alternatively machine learning/neural network models may be trained to learn this relationship in the calibration phase. This calibration scheme assumes that the redistribution of the light within the sensor is stack independent.

As such, disclosed herein is a substrate comprising at least one non-visible target which is invisible to a metrology tool. The non-visible target has a period which does not generate propagating diffraction orders which can be captured by the metrology tool. Also disclosed is a reticle comprising reticle features configured to form such a substrate when exposed in a lithographic process.

As an alternative to using a non-visible target, the effect of surrounding structure can be quantified by calibrating overfilled measurements with underfilled measurements comprising only target structure within the measurement spot (and therefore being unaffected by surrounding structure). Such a method may comprise the following steps:
Measure targets using an underfilled spot.
Measure the same targets with an overfilled spot.
Compute the difference between the underfilled and overfilled measurements; this difference is a measure of the impact of the surrounding on the overfilled measurements.
Correlate this difference to the measurement (intensity/asymmetry) of the surrounding structure (e.g., similarly to the calibration method previously described in relation to the non-visible target).
Correct for asymmetry impact in future measurements by measuring the background (surrounding structure) and applying the relationship deduced from functional behavior as determined in the previous step.

In a further embodiment, a further calibration method consists of measuring the intensity of light reflected from a single pad of the four pad arrangement of FIG. 7. Such measurement gives the information about the amount of light intensity which is available outside the physical boundaries of the pad. The calibration further subtracts a scaled intensity from the actual measured intensity on pads with surrounding pads. In a further embodiment, a plurality of intensity values obtained at each pixel on the detection camera, pixels forming the measured image of target arrangement, are assessed for quality, i.e. by analyzing whether the asymmetries obey a linear behavior. Non-linear behavior pixels are discriminated and excluded and/or labeled. Further, the measured intensity values of the discriminated pixels are used, by way of subtraction for example, to correct the measured values of the non-discriminated pixels for said cross-talk effects.

Methods described herein may find application in any form of metrology on overfilled targets. Such targets can therefore be made smaller; e.g., the targets may be smaller than 40 μm, 30 μm, 20 μm, 15 μm or 10 μm in one or both directions of the substrate plane.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The term target should not be construed to mean only dedicated targets formed for the specific purpose of metrology. The term target should be understood to encompass other structures, including product structures, which have properties suitable for metrology applications. The term target encompasses targets used for alignment, conventionally referred to as alignment marks or marks. Such alignment targets or marks may also comprise actual product structure suitable for use in alignment or dedicated alignment targets.

Further embodiments of the current invention are described in below numbered clauses:

1. A method of metrology comprising:
measuring at least one surrounding observable parameter relating to a surrounding signal contribution to a metrology signal which comprises a contribution to said metrology signal which is not attributable to at least one target being measured;
determining a correction from said surrounding signal observable parameter;
obtaining first measurement data relating to measurement of one or more targets using measurement radiation forming a measurement spot on one or more of said one or more targets which is larger than one of said targets; and
applying said correction to the first measurement data.

2. A method according to clause 1, wherein said surrounding signal contribution comprises a contribution attributable to surrounding structure captured in said measurement spot when measuring said target.

3. A method according to clause 1 or 2, wherein said at least one surrounding signal observable parameter comprises one or more of:
a signal strength or intensity metric corresponding to the surrounding structure;
an amplitude of an interference pattern corresponding to the surrounding structure;
an aligned position and/or fringe position corresponding to the surrounding structure;
an asymmetry corresponding to the surrounding structure;
an intensity imbalance corresponding to the surrounding structure;
a fringe visibility corresponding to the surrounding structure;
a difference between aligned positions for different colors corresponding to the surrounding structure.

4. A method according to any of clauses 1 to 3, wherein said steps of measuring at least one surrounding observable parameter and determining a correction are performed in an initial calibration phase; and said calibration phase further comprises:
determining said correction as at least one correction relationship between at least one surrounding observable parameter and said surrounding signal contribution in said calibration phase.

5. A method according to clause 4, wherein said determining at least one correction relationship comprises determining correction relationships for each of a plurality of different nominal stacks and/or illumination conditions of said measurement radiation.

6. A method according to clause 4 or 5, comprising obtaining calibration measurement data comprising calibration target data and corresponding calibration surrounding observable parameter data.

7. A method according to clause 6, wherein said calibration target data relates to a non-visible target which is invisible to the metrology tool measuring the non-visible target.

8. A method according to clause 7, wherein said non-visible target has a period which does not generate propagating diffraction orders which can be captured by the metrology tool.

9. A method according to clause 7 or 8, wherein said calibration target data describes a metrology signal value for a target region of interest corresponding to said non-visible target within measurement images of said non-visible target; and said determining at least one correction relationship comprises determining at least one correction relationship between said calibration target data and said calibration surrounding observable parameter data.

10. A method according to clause 9, wherein said calibration surrounding observable parameter data is obtained from a surrounding region of interest within said measurement images, such that corresponding sets of calibration surrounding observable parameter data and calibration target data are obtained from respective images.

11. A method according to clause 6, wherein said calibration target data comprises target swing curve data and said calibration surrounding observable parameter data comprises surrounding swing curve data and said step of determining at least one correction relationship comprises comparing said target swing curve data and said surrounding swing curve data.

12. A method according to clause 11, wherein said first measurement data comprises alignment data and said step of determining at least one correction relationship comprises:
performing alignment measurements without any correction on one or more substrates to obtain alignment data,
exposing the substrates and measuring overlay on the exposed substrates to obtain overlay data;
optimizing said at least one correction relationship such that a corresponding correction which would have improved overlay performance with respect to said overlay data had it been applied to said alignment data.

13. A method according to clause 12, wherein said optimization is performed at least initially in said calibration phase.

14. A method according to clause 12 or 13, wherein said optimization is performed in a shadow mode during a substrate manufacturing process, which continuously monitors whether updating the relationship would improve said overlay performance.

15. A method according to clause 6 wherein said calibration target data comprises first calibration target data relating to one or more calibration targets measured in an overfilled mode and second calibration target data relating to said one or more calibration targets measured in an underfilled mode; and the method comprises:
determining a difference between said first calibration target data and second calibration target data; and
   said determining at least one correction relationship comprises determining at least one correction relationship between said difference and said calibration surrounding observable parameter data.

16. A method according to any of clauses 4 to 15, wherein said first measurement data comprises target measurement data relating to said one or more targets and corresponding surrounding observable parameter data relating to surrounding structure which is in the vicinity of said one or more targets.

17. A method according to clause 16, wherein at least a part of said surrounding structure is captured within a measurement spot used to obtain said first measurement data.

18. A method according to clause 16 or 17, wherein said step of applying said correction comprises applying said correction relationship to said surrounding observable parameter data to determine a correction offset; and applying said correction offset to corresponding target measurement data within said measurement data.

19. A method according to any of clauses 16 to 18, wherein corresponding sets of said target measurement data and said surrounding observable parameter data are determined from respective measurement images of each target or groups thereof, said target measurement data relating to one or more target regions of interest in said measurement images and said surrounding observable parameter data relating to one or more surrounding regions of interest within said measurement images.

20. A method according to any of clauses 1 to 3, wherein a first subset of said first measurement data relates to one or metrology targets and a second subset of said measurement data relates to one or more non-visible targets which are invisible to the metrology tool measuring the non-visible target; and said correction is determined from a metrology signal value for a non-visible target region of interest corresponding to said non-visible target within measurement images of said non-visible target.

21. A method according to clause 20, wherein said non-visible target has a period which does not generate propagating diffraction orders which can be captured by the metrology tool.

22. A method according to any preceding clause, wherein said first measurement data comprises one or both of:
post-exposure measurements; and
pre-exposure measurements or alignment measurements.

23. A method according to clause 22, wherein said post exposure measurements comprise one or both of overlay measurements and focus measurements.

24. A method according to any preceding clause, wherein said one or more targets are smaller than 15 μm in one or both directions of a substrate plane.

25. A computer program comprising processor readable instructions which, when run on suitable processor controlled apparatus, cause the processor controlled apparatus to perform the method of any preceding clause.

26. A computer program carrier comprising the computer program of clause 25.

27. A metrology apparatus, comprising:
a support for a substrate comprising said one or more targets;
an optical system for measuring each target;
a processor; and
the computer program carrier of clause 26 such that the processor can control the metrology apparatus to perform the method of any of clauses 1 to 24.

28. A lithographic apparatus comprising:
an illumination system configured to condition a radiation beam;
a patterning device support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate; and
at least one metrology apparatus according to clause 27.

29. A lithographic apparatus according to clause 28; wherein the at least one metrology apparatus comprises an alignment apparatus operable to perform pre-exposure metrology for performing positional metrology for positioning of one or both of the patterning device support and the substrate table.

30. A lithographic apparatus according to clause 28 or 29; wherein the at least one metrology apparatus comprises a post-exposure metrology apparatus for performing post-exposure measurements on a substrate exposed with structures using said lithographic apparatus.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1.-15. (canceled)

16. A method of metrology comprising:
measuring at least one surrounding observable parameter relating to a surrounding signal contribution to a metrology signal that comprises a contribution to the metrology signal that is not attributable to at least one target;
determining a correction from the surrounding signal observable parameter;
obtaining first measurement data relating to measurement of one or more targets using measurement radiation forming a measurement spot on one or more of the one or more targets that is larger than one of the targets; and
applying the correction to the first measurement data.

17. The method of claim 16, wherein the surrounding signal contribution comprises a contribution attributable to surrounding structure captured in the measurement spot when measuring the target.

18. The method of claim 16, wherein the at least one surrounding signal observable parameter comprises one or more of:
a signal strength or intensity metric corresponding to the surrounding structure;
an amplitude of an interference pattern corresponding to the surrounding structure;
an aligned position and/or fringe position corresponding to the surrounding structure;
an asymmetry corresponding to the surrounding structure;
an intensity imbalance corresponding to the surrounding structure;
a fringe visibility corresponding to the surrounding structure; and
a difference between aligned positions for different colors corresponding to the surrounding structure.

19. The method of claim 16, wherein the steps of measuring at least one surrounding observable parameter and determining a correction are performed in an initial calibration phase; and the calibration phase further comprises:
determining the correction as at least one correction relationship between at least one surrounding observable parameter and the surrounding signal contribution in the calibration phase.

20. The method of claim 19, wherein the determining at least one correction relationship comprises determining correction relationships for each of a plurality of different nominal stacks and/or illumination conditions of the measurement radiation.

21. The method of claim 19, comprising obtaining calibration measurement data comprising calibration target data and corresponding calibration surrounding observable parameter data.

22. The method of claim 19, wherein the first measurement data comprises target measurement data relating to the one or more targets and corresponding surrounding observable parameter data relating to surrounding structure that is in the vicinity of the one or more targets.

23. The method of claim 16, wherein a first subset of the first measurement data relates to one or metrology targets and a second subset of the measurement data relates to one or more non-visible targets that are invisible to the metrology tool measuring the non-visible target; and
the correction is determined from a metrology signal value for a non-visible target region of interest corresponding to the non-visible target within measurement images of the non-visible target.

24. The method of claim 16, wherein the first measurement data comprises one or both of:
post-exposure measurements; and
pre-exposure measurements or alignment measurements.

25. A computer program comprising processor readable instructions that, when run on suitable processor controlled apparatus, cause the processor controlled apparatus to perform the method of claim 16.

26. A computer program carrier comprising the computer program of claim 25.

27. A metrology apparatus, comprising:
a support for a substrate comprising one or more targets;
an optical system for measuring each target;
a processor configured to control the metrology apparatus to perform a method comprising:
measuring at least one surrounding observable parameter relating to a surrounding signal contribution to a metrology signal that comprises a contribution to the metrology signal that is not attributable to at least one of the one or more targets;
determining a correction from the surrounding signal observable parameter;
obtaining first measurement data relating to measurement of the one or more targets using measurement radiation forming a measurement spot on one or more of the one or more targets that is larger than one of the targets; and
applying the correction to the first measurement data.

28. A lithographic apparatus comprising:
an illumination system configured to condition a radiation beam;
a patterning device support constructed to support a patterning device, the patterning device is capable of imparting the radiation beam with a pattern in its cross-section to form a patterned radiation beam;
a substrate table constructed to hold a substrate;
a projection system configured to project the patterned radiation beam onto a target portion of the substrate; and
at least one metrology apparatus of claim 27.

29. The lithographic apparatus of claim 28, wherein the at least one metrology apparatus comprises an alignment apparatus operable to perform pre-exposure metrology for performing positional metrology for positioning of one or both of the patterning device support and the substrate table.

30. The lithographic apparatus of claim 28, wherein the at least one metrology apparatus comprises a post-exposure metrology apparatus for performing post-exposure measurements on a substrate exposed with structures using the lithographic apparatus.
